(19) United States
(12) Patent Application Publication
(10) Pub. No.: US 2009/0242019 A1
(43) Pub. Date: Oct. 1, 2009

(54) METHOD TO CREATE HIGH EFFICIENCY, LOW COST POLYSILICON OR MICROCRYSTALLINE SOLAR CELL ON FLEXIBLE SUBSTRATES USING MULTILAYER HIGH SPEED INKJET PRINTING AND, RAPID ANNEALING AND LIGHT TRAPPING

(75) Inventors: Arun Ramamoorthy, Sunnyvale, CA (US); Kenneth R. Pelowski, Atherton, CA (US); Eric R. Sirkin, Palo Alto, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Silexos, Inc, Palo Alto, CA (US)

(21) Appl. No.: 12/338,853

(22) Filed: Dec. 18, 2008

Related U.S. Application Data
(60) Provisional application No. 61/014,965, filed on Dec. 19, 2007.

(51) Int. Cl. H01L 31/04; B05D 5/12; B05D 3/06; B05D 3/10; B29C 35/08; H01L 31/18; C08F 2/48

(52) U.S. Cl. 136/255; 427/74; 427/532; 264/400; 216/13; 136/258; 427/508

(57) ABSTRACT

Embodiments of the present invention relate to fabricating low cost polysilicon solar cell on flexible substrates using inkjet printing. Particular embodiments form polycrystalline or microcrystalline silicon solar cells on substrates utilizing liquid silane, by employing inkjet printing or other low cost commercial printing techniques including but not limited to screen printing, roller coating, gravure coating, curtain coating, spray coating and others. Specific embodiments employ silanes such as cyclopentasilane (C₅H₁₀) or cyclohexasilane (C₆H₁₂), which are liquids at room temperature but undergo a ring opening chemical reaction upon exposure to radiation of a wavelength of ultraviolet (UV) or shorter. . Opening of the rings of the liquid silane converts it into a polymerized material comprising saturated and unsaturated silicon chains of varied length. Heating to approximately 250-400° C. converts these materials into a hydrogenated amorphous silicon film. Controlled annealing at higher effective temperatures causes the amorphous film to change phase to polycrystalline or microcrystalline silicon, depending upon specific processing conditions.

### CROSS-REFERENCE TO RELATED APPLICATION

The instant nonprovisional patent application claims priority to U.S. Provisional Patent Application No. 61/014,965, filed Dec. 19, 2007 and incorporated by reference in its entirety herein.

### BACKGROUND OF THE INVENTION

Solar cells convert photons from the sun into electrons based on the photoelectric effect. Among the various materials being used for PhotoVoltaic (PV) solar cells, crystalline silicon cells are the most suitable since (1) silicon is abundantly available (2) crystalline silicon has a bandgap of 1.1 eV and this is close to being optimal for AM1.5 solar spectrum and (3) silicon processing has been used for a long period of time in the semiconductor industry and cells with highest production efficiencies have been demonstrated with silicon. However, silicon processing requires expensive manufacturing equipment. Further, the recent demand for silicon in solar cells and the lack of silicon wafer capacity has created a silicon shortage and has thus led to a significant increase in silicon prices. While significant wafer capacity is expected to come online in 2008-2009 timeframe, the fundamental cost for manufacturing is not expected to change drastically.

The manufacture of monocrystalline and the lower cost multicrystalline silicon wafers is expensive due to the high capital and power requirements needed in heating the silicon material to its melting point and the stringent purification needs for silicon solar cells. Subsequent processing to convert these wafers into functionally solar photovoltaic panels are also costly. Solar photovoltaic panels based on amorphous silicon films are less costly than those using silicon wafers to manufacture due to the lower consumption of silicon materials and lower capital requirements. However, the capital costs of the required vacuum based equipment and the lower throughput of conventional silicon thin films also result in high cell production costs.

Several thin film technologies including Cadmium Telluride (CdTe) and Copper Indium Selenide (CIS) have demonstrated lower cost of manufacturing, however, they suffer from low efficiencies (5%-8%). These approaches also have cost issues associated with high capital equipment costs and limited throughput.

A lower $/Watt-peak is critical for mass adoption of solar photovoltaics. In order to drive the $/Watt-peak metric lower, both high efficiencies and low cost are needed.

### SUMMARY OF THE INVENTION

This invention addresses the above problem by proposing a high efficiency solar cell made from polysilicon or microcrystalline silicon, using industrial grade inkjet printing and rapid laser anneal. Inkjet printers are relatively inexpensive compared with vacuum based semiconductor deposition tools such as PECVD, LPCVD etc. Further, efficiencies of 12%-16%, and in some embodiments between 10%-16%, can be achieved with large grained polysilicon or microcrystalline thin films deposited using the inkjet printing. A combination of both the low manufacturing cost and the higher efficiency will significantly reduce the $/Watt-peak for the solar cells.

Embodiments of the invention relate to forming low cost polysilicon solar cells on flexible substrates using inkjet printing. Particular embodiments form polycrystalline or microcrystalline silicon solar cells on substrates, including flexible or rigid substrates, utilizing liquid silane, by employing inkjet printing or other low cost commercial printing techniques including but not limited to screen printing, roller coating, gravure coating, curtain coating, spray coating and others. Specific embodiments employ silanes such as cyclopentasilane (C₅H₁₀) or cyclohexasilane (C₆H₁₂), which are liquids at room temperature but undergo a ring opening chemical reaction upon exposure to radiation of ultraviolet (UV) or shorter wavelengths. Opening of the rings of the liquid silane converts it into a polymerized material comprising saturated and unsaturated silicon chains of varied length. Heating to approximately 250-400° C. converts this polymerized material into a hydrogenated amorphous silicon film. Controlled annealing at higher effective temperatures causes the amorphous film to change phase to polycrystalline or microcrystalline silicon, depending upon specific processing conditions.

An embodiment of a process according to an embodiment of the present invention comprises providing a substrate and coating a selected region with a liquid silane. The liquid silane is converted to a polymerized material, and the polymerized material is incorporated as an absorber layer in a photovoltaic cell.

Another embodiment in accordance with the present invention of a process for fabricating a photovoltaic cell, comprises, forming a silicon absorber layer by applying liquid silane to a surface and then applying a heat treatment to the liquid silane, and forming an additional layer over the silicon absorber layer.

An embodiment of a photovoltaic cell in accordance with the present invention, comprises a substrate, and a polycrystalline silicon absorber layer formed over the substrate and having a thickness of between about 0.5-20 μm and comprising a P/N junction.

A further understanding of embodiments in accordance with the present invention can be made by way of reference to the ensuing detailed description taken in conjunction with the accompanying drawings.

### BRIEF DESCRIPTION OF THE DRAWINGS

FIG. 1 is a simplified depiction of light trapping using a blazed grating approach.

FIG. 2 shows a simplified depiction of light trapping using a sinusoidal grating approach.

FIG. 3 shows a simplified depiction of light trapping using Lambertian reflectance.

FIG. 4 shows a simplified cross-sectional view of an embodiment utilizing curtain coating of liquid silane on a glass substrate.

FIGS. 5A-C show different views of inkjet printing of liquid silane on a substrate.

FIGS. 6A-C show different views of UV curing of the liquid silane.

FIGS. 7A-C show different views of heating of polymerized silane.

FIGS. 8A-C show different views of laser annealing of amorphous silicon.

FIGS. 9-9A are simplified plan and cross-sectional views, respectively, showing the use of laser ablation of TCO to isolate PV cells.

FIGS. 10-10A show cross-sectional and enlarged cross-sectional views, respectively, of a superstrate cell design with TCO texturing.

FIGS. 11-11A show cross-sectional and enlarged cross-sectional views, respectively, of a substrate cell design with TCO texturing.

FIG. 12 shows a simplified cross-sectional view of an embodiment having a grating structure formed on a back reflector.

FIG. 13 shows a simplified cross-sectional view of an embodiment having a grating structure formed on a cell.

FIGS. 14-14A show simplified cross-sectional and enlarged cross-sectional views of an embodiment of a bifacial cell.

FIGS. 15-15A show simplified cross-sectional and enlarged cross-sectional views, respectively, of an embodiment of a cell according to the present invention which is integrated with Cd:Te.

### DESCRIPTION OF THE INVENTION

Particular embodiments of the present invention form polycrystalline or microcrystalline silicon solar cells on substrates (which may be flexible or rigid) utilizing liquid silane, by employing inkjet printing or other low cost commercial printing techniques including but not limited to screen printing, roller coating, gravure coating, curtain coating, spray coating and others. Specific embodiments employ silanes such as cyclopentasilane (C₅H₁₀) or cyclohexasilane (C₆H₁₂), which are liquids at room temperature but undergo a ring opening chemical reaction upon exposure to radiation of ultraviolet (UV) or shorter wavelengths. Opening of the rings of the liquid silane converts it into a polymerized material comprising saturated and unsaturated silicon chains of varied length. Heating to approximately 250-400° C. converts these materials into a hydrogenated amorphous silicon film.

Controlled annealing at higher temperatures causes the amorphous film to change phase to polycrystalline or microcrystalline silicon, depending upon specific processing conditions. Embodiments of the present invention may be employed to form silicon films having grain sizes ranging from about 0.5-20 μm, with specific embodiments having grain sizes in the 3-4 cm range.

A benefit offered by embodiments of the present invention is that it entails the use of low cost, commercially available processing equipment operating at atmospheric pressure with short cycle times, low material consumption, and moderate temperatures. These features substantially reduce the cost of processing thin photovoltaic silicon films.

Due to the low cost of fabricating active absorber layers in this manner, embodiments of the invention can be applied as an additive process to the manufacture of other types of solar cells, including but not limited to silicon (including single crystal silicon, polycrystalline silicon, or amorphous silicon), Cd:Te, and Copper Indium Gallium Selenide (CIGS). An embodiment of a PV cell created from such a process would have existing layer(s) made from traditional techniques, and one or more additional layers made utilizing an approach according to present invention. Embodiments of the present invention can increase the overall cell efficiency at marginal additional cost.

While PV cells manufactured utilizing embodiments of the present invention achieve lower costs than current PV manufactured cells, they can also achieve equal or greater efficiencies than commercially available cells. To allow this, embodiments of the present invention may integrate methods enhancing solar light collection efficiency.

One such approach to improve light collection efficiency is by texturing the substrate and/or one of the deposited layers. Another method for improving light collection is through the integration of diffraction grating structures into one of the films. Both approaches significantly increase the path that the light traverses through the silicon film, so more of the incident light is absorbed and converted into charge carriers.

Another approach for collecting more light is to use the liquid silane to fabricate bifacial cells. In such bifacial cells, the active absorber layer is on both sides of a planar cell. External optics collect light and expose both sides of the cell.

Particular embodiments utilize the formation of a liquid silane film by inkjet printing. In this approach, inkjet printing will be used to deposit various layers for the solar cell, size (x-y) including the absorber, the transparent conducting oxide (TCO), the anti reflective (AR) coating and the contact metallization. Rapid anneal using lasers or flash lamps will be used to form large grained polysilicon or microcrystalline films from the deposited amorphous silicon films. A laser can further be used to isolate the solar cells. Finally, inkjet printing will be used to form the contact metallization.

They key elements of this embodiment of the invention are:
1. High speed inkjet printing to deposit a layer of undoped or n and p type doped amorphous silicon from silane, polysilane or cyclosilane based inks;
2. Rapid anneal (laser or thermal) to crystallize the film and reduce defects;
3. High speed inkjet printing of the antireflective coating and transparent conducting oxide (TCO) films;
4. Light trapping techniques to enhance the cell efficiency;
5. Laser scribing to isolate the cells; and
6. High speed inkjet printing of contact metallization.

A variety of embodiments are encompassed by the present invention. According to certain embodiments, a liquid coating system such as inkjet printing or another technique may be used is used to deposit the liquid silane that, after UV exposure and thermal processing, forms the photo-active semiconductor layer.

Such liquid coating may be integrated into an overall process flow that will include either the liquid or vacuum coating of other films used in the formation of a complete solar photovoltaic cell. Examples of such other films include but are not limited to, transparent conducting oxide, anti-reflective coating, and metallization.

Rapid anneal using lasers, thermal anneal, or flash lamps may be employed to form large grained polycrystalline silicon or microcrystalline films from the deposited amorphous silicon films. Lasers may be further used to “cut” into the active semiconducting or conducting layers to electrically isolate the solar cells, or to open windows to the p or n junction layers for metal contact formation. Inkjet printing or alternative liquid coating technologies, or vacuum coating, may used to form the contact metallization.

Elements of such embodiments include:
1. High speed inkjet printing, or other liquid coating technologies, to deposit a layer of undoped or n and p type doped silane, polysilane or cyclosilane based inks;
2. The combination of intense UV radiation exposure and heat to induce polymerization of the liquid inks to solid polysilane material;
3. Temperature processing of the solid polysilane to convert it to amorphous silicon;
4. Rapid anneal (laser, thermal, flash lamps, or other) to crystallize the film and reduce defects;
5. High speed inkjet printing, or other liquid or conventional vacuum coating, of the antireflective coating and transparent conducting oxide (TCO) films;
6. Light trapping techniques to enhance the cell efficiency;
7. Laser scribing to isolate the cells and open contacts to the active layers;
8. High speed inkjet, or screen printing of contact metallization;
9. The use of these techniques for the purpose of improving the overall system efficiency in concert with existing processes for other photovoltaic technologies such as single crystal silicon, multicrystalline silicon, Cd:Te, Copper Indium Selenide (CIS), ITT-V materials or other.
10. The inexpensive integration of this technology as a bifacial cell in which light can enter from both sides of a planar photovoltaic cell with separate photo-active layers on each side.

Currently, most non-silicon based thin film solar cells suffer from low efficiencies. Due to the bandgap and material properties, crystalline silicon is a better absorber and has demonstrated higher efficiencies than other thin film materials such as CIS and CdTe. Even though the other thin film technologies have lower efficiencies, they also have lower manufacturing costs than traditional silicon. The approach proposed in this invention provides both the high efficiency of crystalline silicon while simultaneously offering a path for low cost manufacturing of these solar cells.

For traditional crystalline silicon based solar cells, the current state of art is creating a p-n junction using a p and n type silicon with back contacts. SunPower has demonstrated such solar cells with efficiencies in the 20.0%-22.0% range. The manufacture of high quality single crystal silicon wafers with the minimal impurity and low defect levels needed for this type of efficiency, is costly. Both the shortage of wafers and the rising material costs have resulted in the development of alternative thin film based approaches. The well known thin film approaches involve Cadmium Telluride (CdTe), Copper Indium Selenide (CIS) and amorphous silicon (a:Si). Most of these thin film based approaches use physical or chemical deposition to deposit the absorber.

The amorphous silicon solar cells are typically deposited by Plasma Enhanced Chemical Vapor Deposition (PECVD) from silane gas. However, due to doping induced defects that reduce carrier lifetime, a:Si cells are typically fabricated as p-i-n structures. They also suffer from light induced degradation (Staebler-Wronski effect) and typically have lower efficiencies. Most a-Si cells are thus constructed as multifunction cells along with a SiGe. Further, the deposition rate of the best materials using PECVD is around 1 Å/Sec, which limits the mass production of very good quality a-Si cells. The inherent high capital and maintenance costs of the large vacuum equipment in concert with the low film deposition rates contributes to a resulting high cost of manufacture.

While CdTe at a bandgap of 1.45 eV has high optical absorption and is a direct bandgap material and is ideally suited for solar applications, the best production solar cells have efficiencies around 10.0%. Toxicity with CdTe solar cells and long-term shortage of Tellurium have been brought up as potential concerns. Deposition techniques for CdTe such as sublimation-condensation, closed space sublimation, chemical vapor deposition or atomic layer epitaxy require significant capital expenditures, though this capex is lower than traditional silicon processing.

Copper Indium DiSelenide (CIS) is the most efficient heterojunction thin film technology to date with efficiencies of 18.1% demonstrated on a 0.5 cm² lab cell at NREL and 14.7% for mini-modules of 20 cm². Due to its complicated phase diagram as a ternary alloy (with Gallium) and narrow existence range for single phase CIS, it is quite challenging to deposit these films with the right stoichiometry. Further, these films have a tendency to form a large number of intrinsic defects. The deposition process is also complicated and expensive due to the co-evaporation of copper, indium and selenium. This occurs in a vacuum chamber, there entailing costly capital equipment with low throughput.

All the individual components being proposed here have been shown to work in other applications such as semiconductor device processing.

1. Microcrystalline or polycrystalline silicon thin film solar cells have been fabricated with efficiencies in the high single digits. Theoretical efficiencies for crystalline silicon thin film cells are predicted to be around 12%-18%, and in some embodiments between 10%-18%. But these require special cell designs to maximize collection efficiency.
2. The proposed inkjet based deposition techniques for n-silicon or p-silicon has been demonstrated for RFID applications by several companies including Sony, Sharp, etc. These companies have shown silicon films with carrier mobilities comparable to traditional silicon films deposited by PECVD.
3. Techniques such as a thermal anneal are being used today by companies such as Crystalline Silicon on Glass. However, due to substrate limitations, they are restricted from processing at higher temperatures that are required for crystalline with large grains. Pulsed laser annealing have been used to create large grained polysilicon in semiconductor and LCD applications. Double pulsed laser anneal has been demonstrated for poly-Si TFT LCDs. Use of intense, pulsed Xenon lamps has also been shown to convert amorphous into polycrystalline silicon.
4. The various light trapping techniques being proposed here have been shown to work in various other cell structures and applications. The use of these techniques to increase the light capture efficiency of inkjet printed and laser annealed cells is unique.

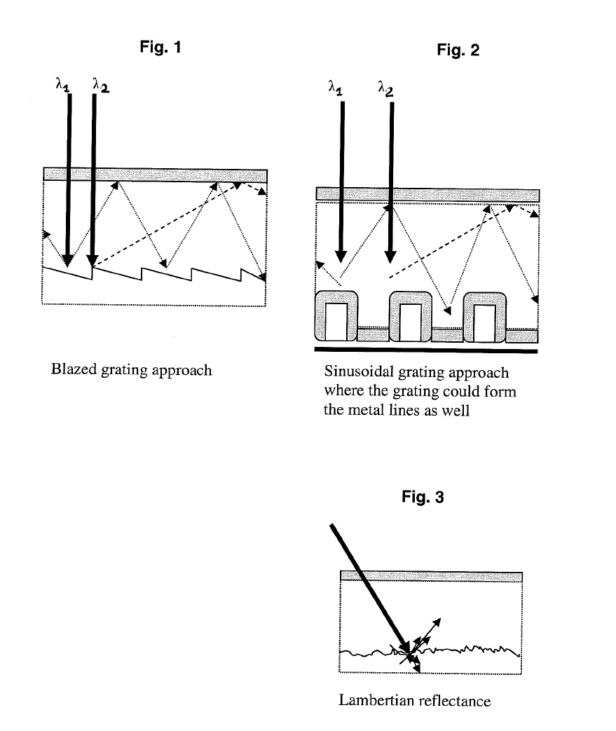

In certain embodiments the liquid silane may be formed by inkjet printing. In this approach, a thin film of amorphous silicon (a-Si:H) will be deposited using industrial grade inkjet printing on flexible substrates such as stainless steel, aluminum, etc. The film will be printed from various silicon based inks such as silane, polysilane, cyclosilane, etc. In a specific embodiment, the ink comprises nanoparticles of amorphous characteristic. These inks can include dopants such as boron or phosphorus to create the n-type and p-type inks for the emitter and base regions. In the case of doped films, these can be directly inkjet printed onto the substrate. If these inks are non-doped, then an extra step will be needed to create doped films. This can also be, accomplished using a spin-on film to incorporate the required dopants. The silicon films deposited will need to be in the range of 1 μm-20 μm in thickness, and in certain embodiments the thickness can range from about 0.5-20 μm. These can be accomplished with commercially available inkjet printers with scan speeds in the 200 mm/s-500 mm/s, firing rate of 2 KHz-10 KHz, droplet volumes of 1 picoliter-20 picoliter, 128 nozzle print heads, ink viscosities in the 1-15 cP range and print accuracy of 5-7 um. This amorphous silicon film will then be crystallized using a rapid laser anneal or lamp based rapid thermal anneal (RTA) process. This can be accomplished by short pulsed lasers including excimer lasers (193 nm, 248 nm, 308 nm), argon-ion lasers and other longer wavelength lasers or halogen based flash lamps in the case of rapid thermal anneal. An inert environment such as an Argon and/or Nitrogen environment should be used during the printing of the absorber layer as well the annealing process in order to minimize the incorporation of oxygen. Localized temperatures in the range of 500° C.-650° C., and in some embodiments between 400° C.-800° C., will be needed for optimal grain growth. The process parameters for the anneal process can be optimized to obtain grain sizes in the range of 1 um-20 um, and in some embodiments between 0.5-20 um. In an embodiment, the grains are often columnated or other desirable shape. In order to increase the efficiency of the cell various light trapping techniques could be employed in the cell. These include use of blazed (FIG. 1) or sinusoidal (FIG. 2) gratings and Lambertian reflectance (FIG. 3) using surface texturing (see pictures). Inkjet printing can also be used to deposit the transparent conducting films, the anti reflective films and the contact metallizations. The texturing can be done using various etching processes. For the transparent conducting films, nanoparticulate inks made of transition metal oxides (e.g. antimony tin oxide, porous tin oxide) can be inkjet printed followed by annealing. Antireflective (AR) coatings with refractive index between 1.2-1.5 can be inkjet printed to improve the collection efficiency of the cell. AR coatings made from nanoporous materials (including polyelectrolyte multilayers) can be used. These can be graded as well to improve broadband anti-reflection properties. Conformal deposition and better resolution and aspect ratios can be obtained with inkjet printing of contacts and can thus improve the solar cell performance. Contact metallization can be done with inkjet printing of conductive inks such as Ag, Au, Cu, Pd etc. Finally, the cells can be encapsulated using encapsulants such as EVA (ethylene vinyl acetate).

Certain silane materials, specifically cyclopentasilane C₅H₁₀ or cyclohexasilane C₆H₁₂, are liquids at room temperature. Derivatives of these molecules, whether larger ring structures and/or incorporating Boron, Phosphorous or other types of ligands attached to one or more of the silicon atoms, may be liquids as well.

In one embodiment the liquid silane includes either Boron (or other type III element), and/or includes Phosphorus (or other type V element). When diluted to the proper concentration and subsequently processed, films formed using these doped silanes inherit the corresponding p or n type electrical characteristics.

In certain embodiments, the liquid may contain nanoparticles of polymerized silane to control viscosity and thus the thickness and appropriateness of the method of application. A variety of these materials, with the proper precautions of temperature and atmospheric control can be used to create a silicon based solid film.

According to particular embodiments of the invention, commercial inkjet systems may coat the liquid silane on a flexible substrate such as thin stainless steel that may be coated with an insulator, or on durable plastic sheets at atmospheric pressures and ambient temperatures. In this way the need for expensive, low throughput vacuum based deposition equipment requiring elevated heating of the substrate, is avoided.

Moreover, many plastic materials cannot endure the needed temperatures for vacuum deposition making it impossible to form good quality silicon films any other way. Plastics, and flexible thin sheet metals, have the advantage of very low material cost and allow the integration of active photovoltaic devices into building architectural elements. Embodiments of the invention also encompass the use of fixed or rigid substrates such as sheet glass.

After processing, the thickness of the silicon films may be in the range of about 0.5-20 μm, depending on the desired final cell properties. In the case of inkjet printing, this can be accomplished with commercially available equipment having scan speeds in the range of 200 mm/s-500 mm/s, a firing rate of between about 2 KHz-10 KHz, droplet volumes of 1 picoliter-20 picoliter, 128 nozzle print heads, ink viscosities in the 1-15 cP range, and print accuracy of 5-7 um.

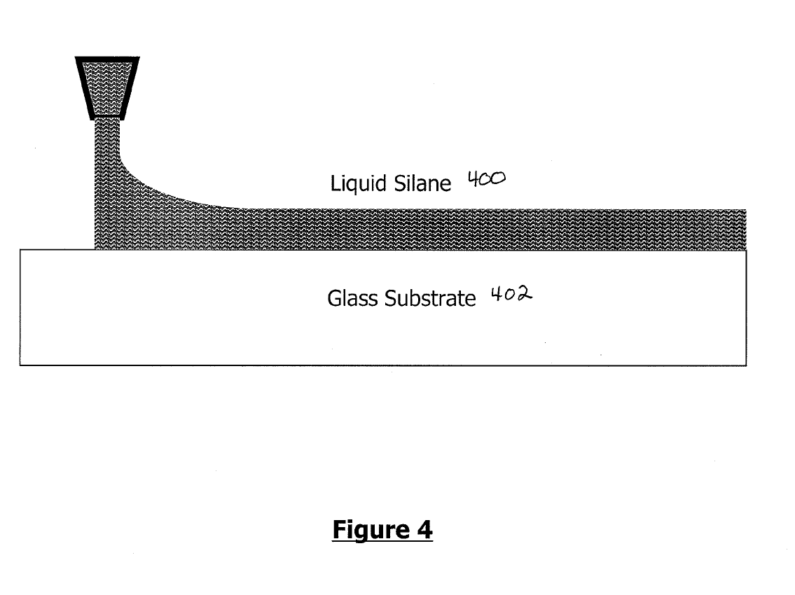

As another example, a spray coater (ultrasonic or other) can coat a 1×1 m2 glass substrate with a liquid in the 20-50 cP range to a thickness of 10 μm in one minute. A gravure coater is capable of coating a fixed or flexible substrate with a liquid in the 10-60 cP range to a thickness of 20 μm at a rate of 0.5 meter per second. Other coating techniques that may be employed by embodiments of this invention include, but are not limited to, spray, gravure, curtain, roller, screen print, and immersion. FIG. 4 shows a simplified cross-sectional view of an embodiment utilizing curtain coating of liquid silane 400 on a glass substrate 402.

Exposing the liquid silane material radiation of UV wavelength or shorter, induces the ring opening of the cyclic silanes, and polymerization. With sufficient radiation all the liquid material is converted into a solid powder. Heating the resultant material to a temperature range of 250-350° C. causes it to convert to a fully amorphous silicon film. The amount of material loss and H₂ content in the film is controlled by the ambient atmosphere and temperature ramp/dwell time.

In certain embodiments, the temperature is kept below 600° C., and the amorphous silicon may be heat treated in an H₂ containing atmosphere. This allows the hydrogen to passivate the dangling bond defects in the amorphous film.

Embodiments of the present invention permit the formation of polycrystalline silicon films of substantially greater thickness than are available utilizing conventional deposition techniques. In particular, certain embodiments of the present invention allow for the formation of polycrystalline silicon layers having a thickness of between about 0.5-20 μm. In some embodiments, the polycrystalline silicon is between about 2-10 μm in thickness, and in some embodiments the polycrystalline silicon is between about 4-6 μm in thickness.

Conversion of the amorphous silicon film to polycrystalline requires elevated temperatures. Care should be taken not to exceed temperatures and dwell times that cause damage to other materials found in the substrate.

Apart from quartz, most glass materials cannot withstand temperatures exceeding 800° C. without deforming or losing their tempering. Metal films such as aluminum cannot withstand sustained temperatures above 550° C. without either reacting with silicon to form an alloy or in some cases oxidizing.

To maintain the integrity of other materials in the cell, it may be important to maintain the annealing temperature either at a high effective temperature for a very short period of time, or at a moderate temperature for a longer period of time. Laser annealing through the scanning of the amorphous silicon film using a high powered laser, can cause the heat to be localized to the silicon film and the effective temperature to reach >900° C. with a dwell time less than 1 second. Short pulsed lasers including excimer lasers (193 nm, 248 nm, 308 nm), argon-ion lasers, and other longer wavelength lasers may be used to convert the amorphous film to polycrystalline. The ambient atmosphere during the annealing process can be controlled to keep O₂ levels at a minimum. Flows of inert gases such as nitrogen or Argon can be used for this purpose.

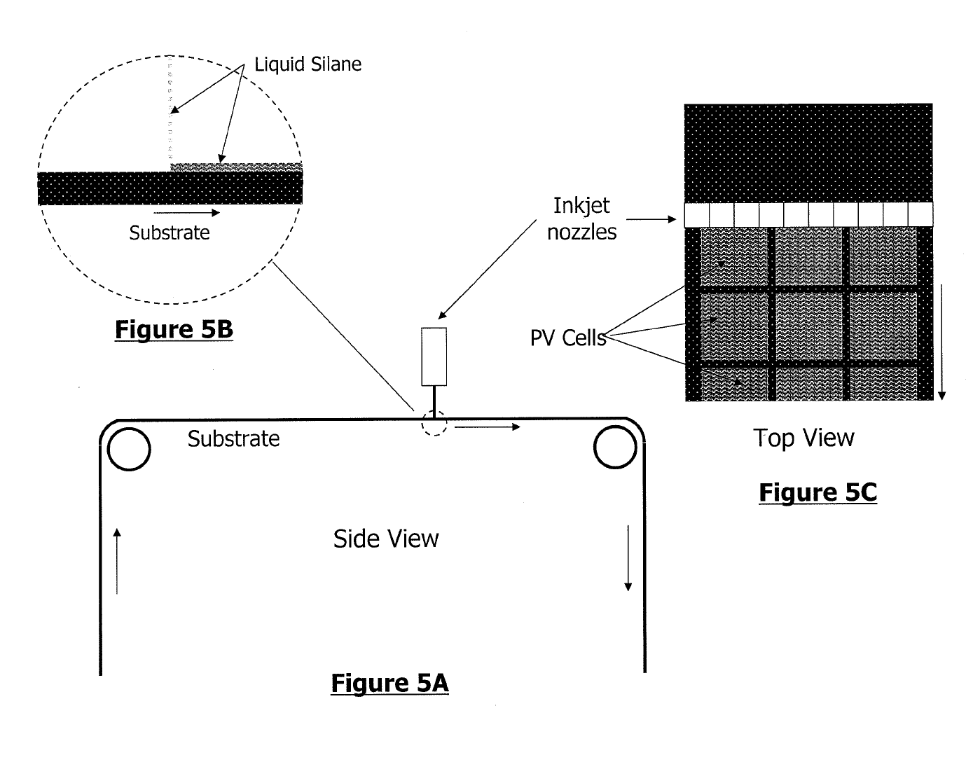

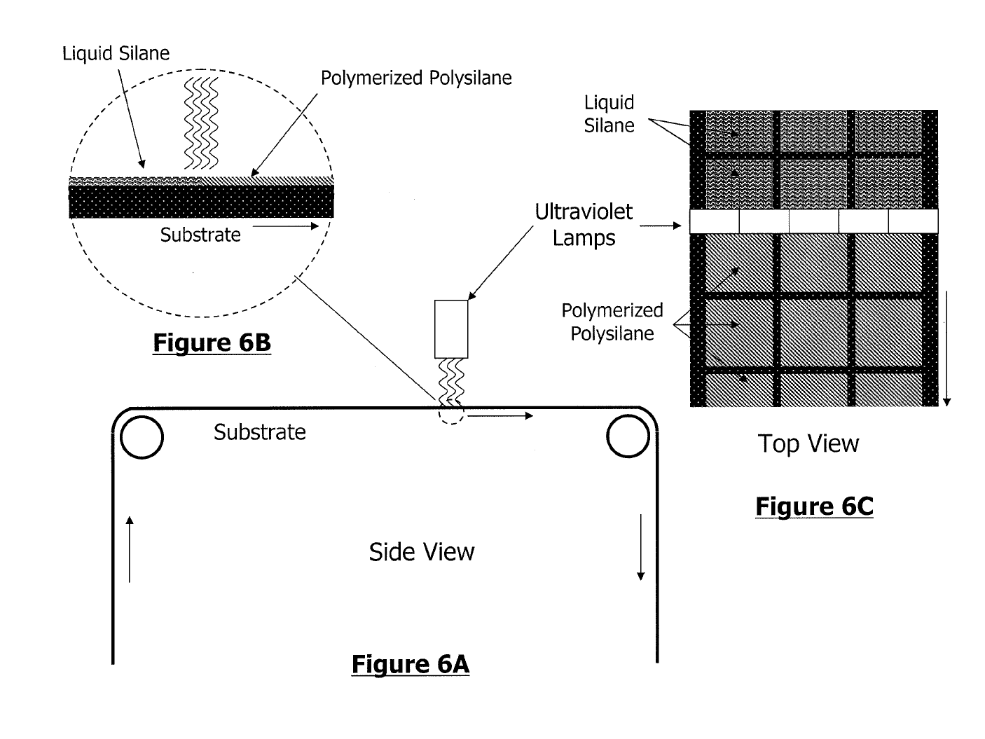

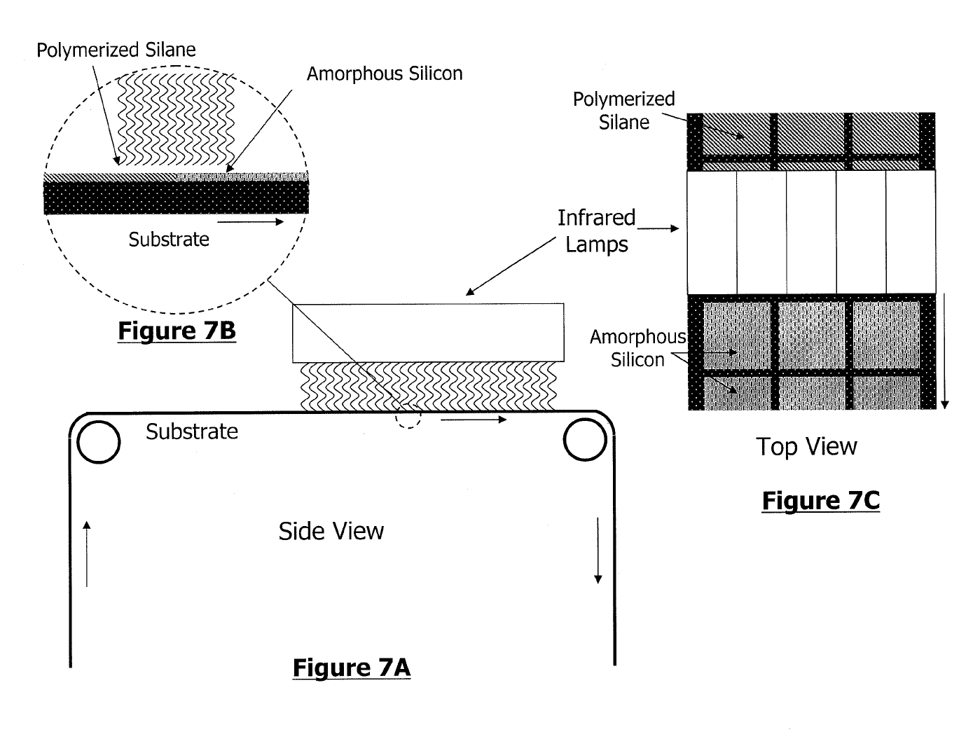

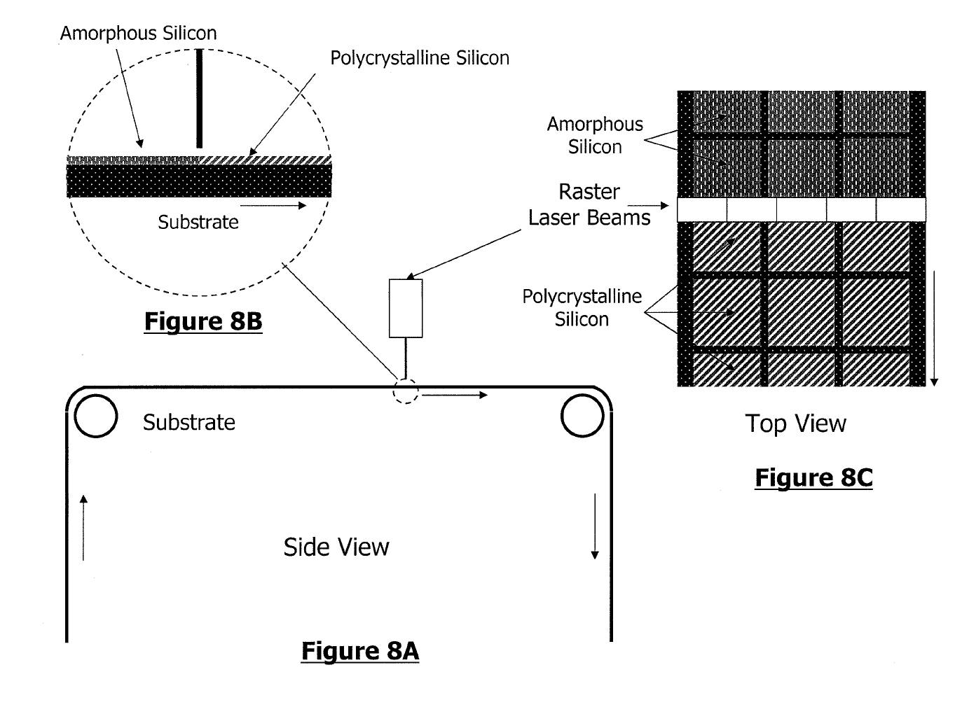

FIGS. 5A-8C show different views of an embodiment of method in accordance with the present invention. Specifically, FIGS. 5A-C show a side view, an enlarged side view, and a top view of an embodiment showing inkjet printing of liquid silane on a substrate. FIGS. 6A-C show the corresponding views of UV curing of liquid silane on a substrate. FIGS. 7A-C show corresponding views of heating of polysilane on a substrate. FIGS. 8A-C show corresponding views of laser annealing of amorphous silicon on a substrate.

According to certain embodiments, alternative annealing techniques other than laser can be employed. These include the use of flash lamps, optical furnaces, rapid thermal annealing (RTA), and conventional furnaces. Apart from conventional furnaces (which rely on exposing the material to temperatures around 600° C. for more than 20 hours), these techniques may rely on exposure to effective temperatures exceeding 850° C. with dwell times below 1 second. These short time periods permit the re-crystallization process, but are short enough to prevent any damage to other materials or the substrate itself.

Grain size, and orientation of the polycrystalline silicon films, are dependent upon growth conditions such as time, atmosphere, and temperature, as well as on the morphology of the underlying films. Grain growth is dependent on silicon atom diffusion and proper nucleation sites on the underlying surface. Use of aluminum films with modest texturing —plasma or acid—are known to be effective at growing grains larger than 1 μm.

Photovoltaic solar cells rely on the creation of an electric field in a diode structure formed by a silicon junction between n-doped and p-doped layers. In one embodiment, a p-n junction is formed by coating a substrate with n type silane material followed by p type, or vice-versa. Annealing of the two distinct layers is done after both have been coated, but another technique permits the annealing of each separately. Junctions having sharp transitions in dopant concentration such as those formed in this fashion, improve the carrier collection and thereby the current and power of the photovoltaic devices.

An alternative method of forming the diode junction uses diffusion of either a spin on dopant containing Boron or Phosphorous, or firing in a furnace with a Boron or Phosphorous containing gas.

The active silicon photovoltaic diodes that are formed are integrated with substrates, metallization, cell interconnection/isolation, and other films, to form a fully operational solar cell. To improve the cell efficiency, proper light collection of the incident sunlight is desirable.

In one embodiment, a Transparent Conducting Oxide (TCO) is deposited either before the silicon absorber layers (in the case of a superstrate cell design), or after the absorber layers (in a substrate design). The TCO layer can be vacuum deposited, or formed by coating the substrate with nanoparticulate inks made of transition metal oxides (e.g. antimony tin oxide, porous tin oxide) followed by annealing.

The TCO layer is electrically conductive yet transmits (>85%) of the incident sunlight. Some embodiments of the invention may make use of Aluminum doped Zinc Oxide (AZO) as the TCO layer. Alternative embodiments could use other TCO films, such as Indium Tin Oxide, Tin Oxide, Zinc Oxide, Antimony Tin Oxide or others.

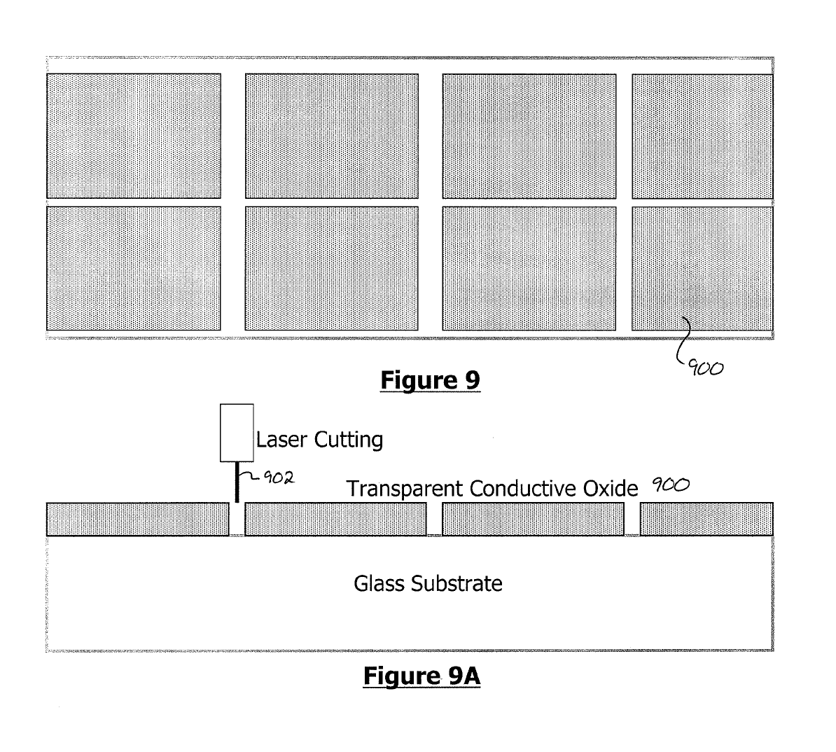

Once TCO is formed as a layer, TCO material between adjacent cells may be removed to electrically isolate them. FIGS. 9-9A are simplified plan and cross-sectional views, respectively, showing the use of laser ablation/cutting of a TCO 900 to isolate PV cells. In one embodiment, laser radiation 902 of a wavelength of 532 nm is used to scribe the TCO layer and isolate the individual solar cells. In alternative embodiments, laser radiation of other wavelengths can be used, such as 355 nm or 1064 nm using optical harmonics of diode lasers. Other lasers such as Excimer lasers operating at 193, 248 or 308 nm, as well as Argon Ion lasers operating at a multitude of wavelengths such as 351, 454.6, 457.9, 465.8, 476.5, 488.0, 496.5, 501.7, 514.5 or 528.7 nm, can also be employed for this purpose.

And while FIGS. 9-9A show an embodiment wherein a laser is used to isolate cells by ablating only the TCO layer, this is not required. In accordance with alternative embodiments, a laser may used to ablate the active silicon absorber layer to open a contact window to the bottom-most conductive layer of the cell. In accordance with still other alternative embodiments, a laser may be used to ablate through a layer to open a contact window to the topmost active silicon absorber layer.

Embodiments of the invention may utilize the texturing of the TCO layer to aid the light collection by the absorber layer. By texturing the surface of the TCO layer, incident light refracts at an angle off normal into the absorber silicon layer. This increases the effective light path and the amount of light that is absorbed.

The film can be textured through the use of a light acid dip for a few seconds. This creates a random surface roughness with features below 1 m in size. Alternatively, the film can be deposited in a fashion that textures the surface as it is formed using Low Pressure Chemical Vapor Deposition (LPCVD). A third approach to imparting texture to the TCO surface is to expose the film to a brief plasma etch in vacuum.

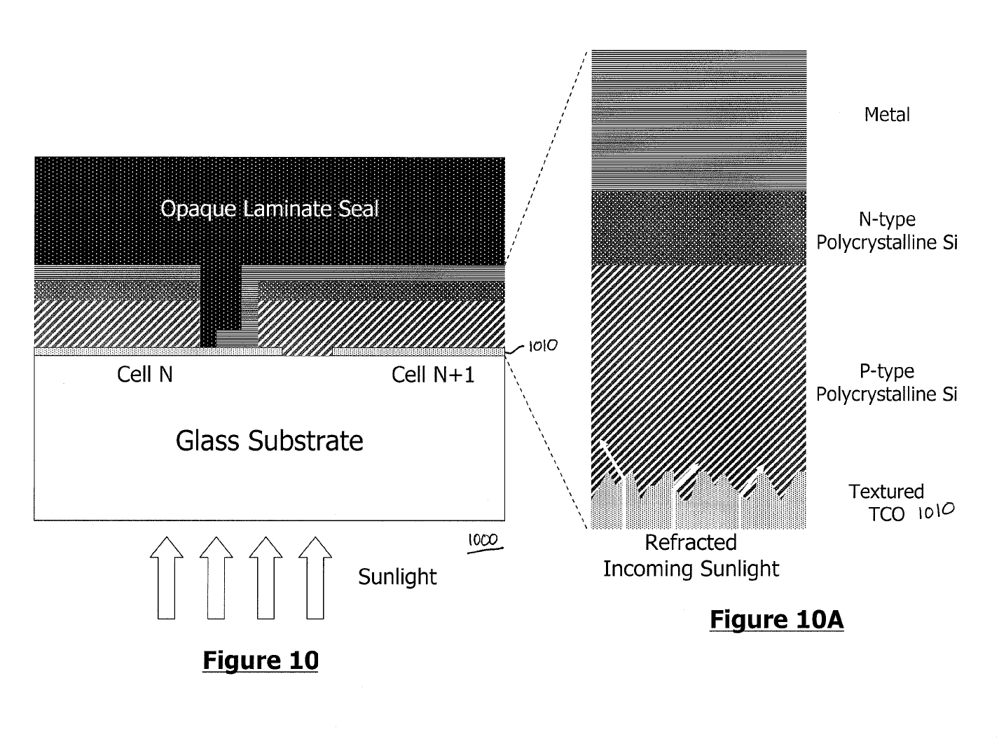

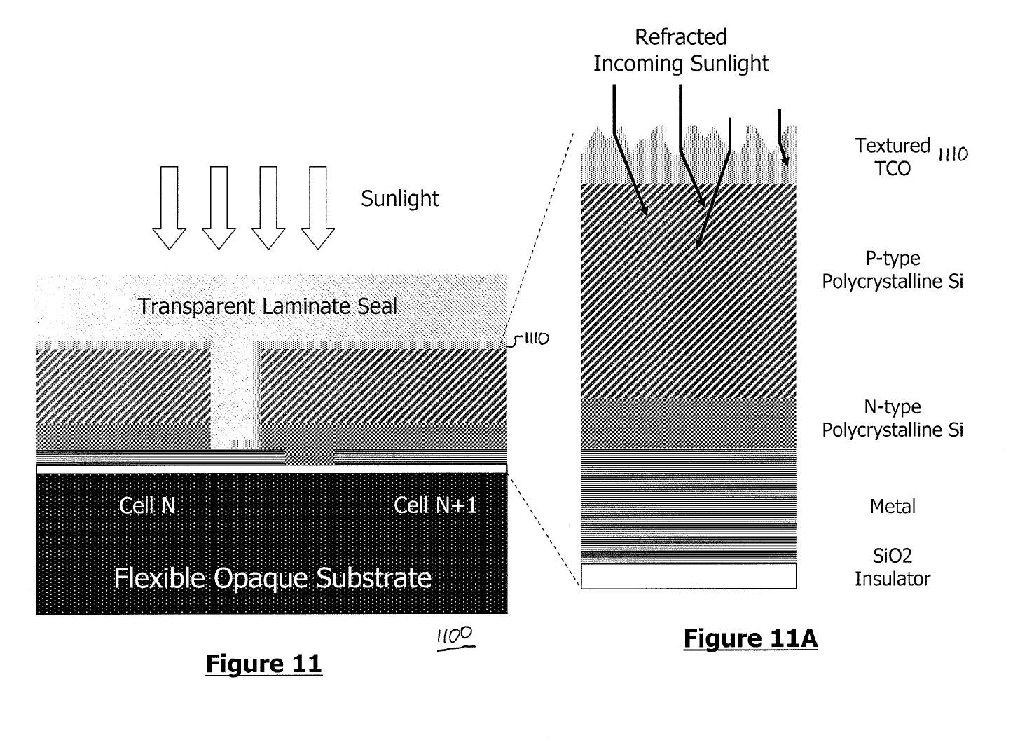

One or more of these texturing techniques can be used in combination in the photovoltaic manufacturing process. The texturing aids the cell efficiency regardless whether it is applied in a superstrate or substrate design. FIGS. 10-10A show cross-sectional and enlarged cross-sectional views, respectively, of a superstrate cell design 1000 employing texturing of a TCO layer 1010. FIGS. 11-11A show cross-sectional and enlarged cross-sectional views, respectively, of a substrate cell design 1100 employing texturizing of a TCO layer 1110.

Another approach for enhancing PV cell efficiency through enhanced light collection, is the use of diffraction gratings embedded in the cell design. Diffraction gratings are formed by a series of parallel lines spaced apart by distances approximating the wavelength of light to be dispersed.

The well-known diffraction grating law predicts the angle at which incident light is refracted based on the wavelength of light and the spacing between the lines:

d*(sin θₘ+sin θᵢ)=mλ, where:
d=spacing between lines in μm;
θₗ=angle of incident light relative to normal;
θₘ=angle of refracted light relative to normal;
m=an integer; and
λ=the wavelength of light in μm.

The diffraction grating lines may be exposed in photoresist covering the substrate, using either holography or a photomask exposing either a positive or negative image. Upon subsequent development of the photoresist, etching of the underlying area, and removal of the photoresist, the diffraction grating image is left on the substrate.

The underlying film should have an index of refraction different from the substrate layer. Either SiO₂ or Si₃N₄ form compatible films that permit imaging of the diffraction grating, although other embodiments would include a metal or other film.

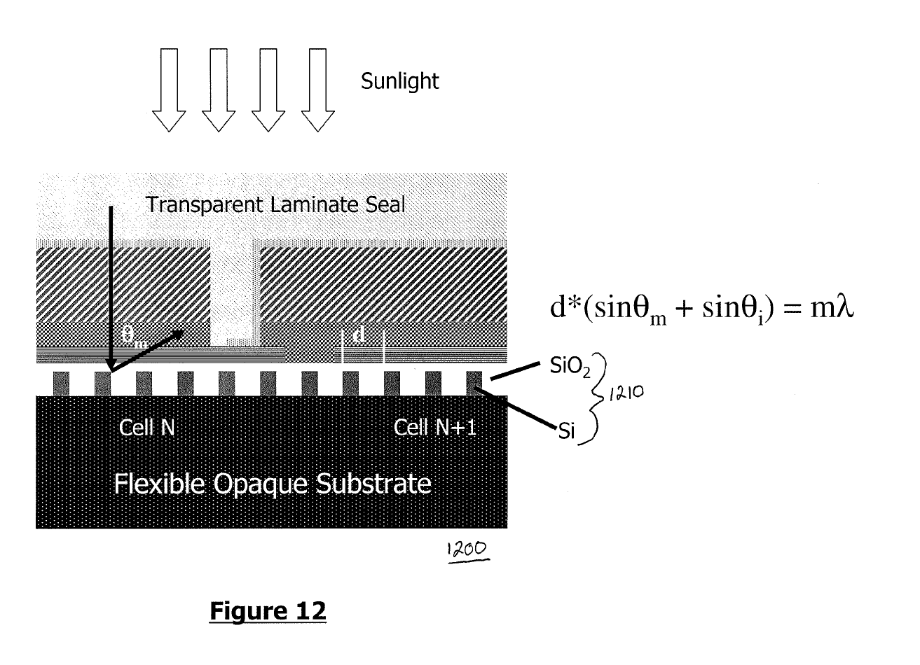

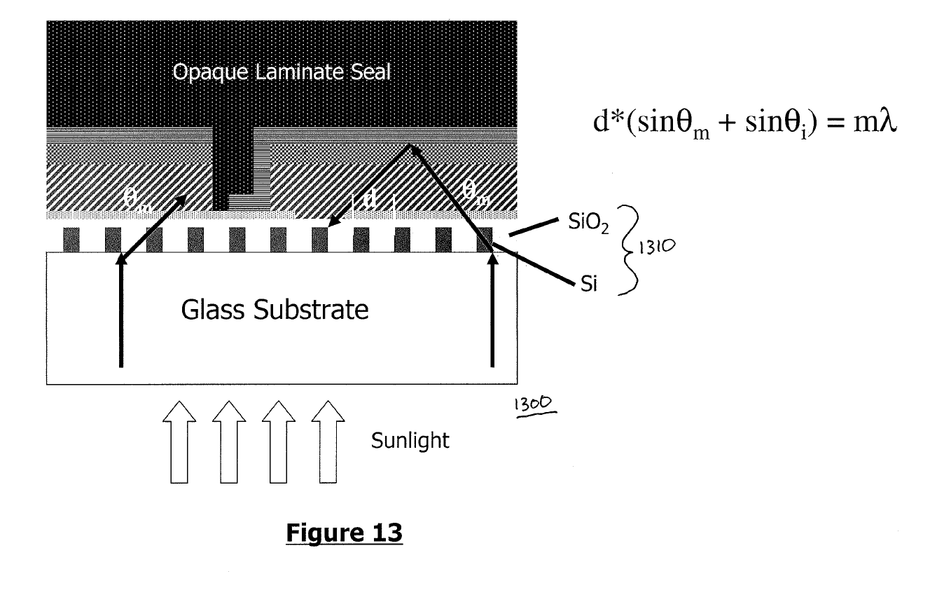

FIG. 12 shows a simplified cross-sectional view of an embodiment of a substrate-type device 1200 having a grating structure 1210 formed on a back reflector. FIG. 13 shows a simplified cross-sectional view of an embodiment of a superstrate-type device 1300 having a grating structure 1310 formed on a cell.

Light collection and solar cell efficiency may also be increased through the construction of a bifacial cell with active absorber layers on both sides of a plane facing the sun. As a result of the low cost fabrication of thin film polycrystalline solar cells offered by embodiments of the present invention, it is economical to manufacture and deploy these bifacial photovoltaic cells. In such embodiments, light is collected using a series of reflectors around the solar cell and reflected onto the rear surface of the cell.

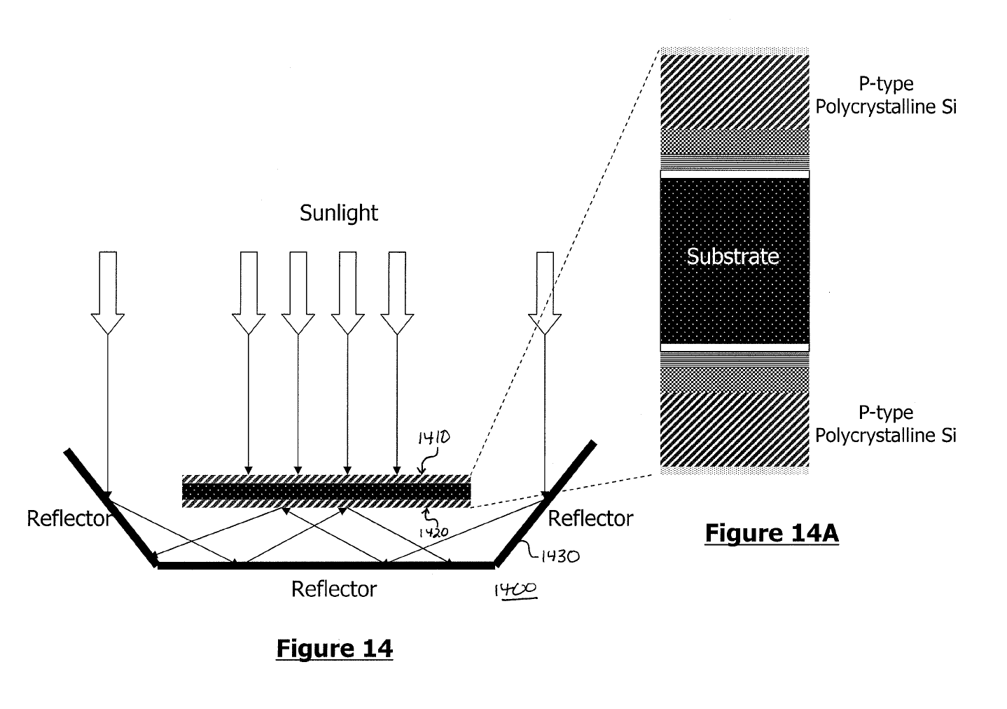

FIGS. 14-14A show simplified cross-sectional and enlarged cross-sectional views of an embodiment of a bifacial cell. Bifacial cell 1400 includes a first side 1410 configured to receive incident light directly, and a second side 1420 configured to receive light from a reflector 1430. In this particular embodiment, the P/N junctions on the first and second side are of the same type, but this is not required. In accordance with alternative embodiments, the P/N junctions on the opposite sides of the substrate could be of different types.

The low costs of polycrystalline thin film solar cells offered by embodiments of the present invention permit their economic integration with existing photovoltaic technologies, to improve the overall cell efficiencies. For example, amorphous silicon semiconductors have a larger bandgap than single crystal silicon, and therefore absorb sunlight at shorter wavelengths efficiently.

Hence a liquid silane film could be coated onto a single crystal silicon solar cell, prior to metallization, and processed to create an amorphous silicon photo-active junction inexpensively. In this case, embodiments of the invention are used to create the low cost amorphous silicon absorber layer, and the conversion efficiency is higher and the cost per watt lower, than could be achieved otherwise.

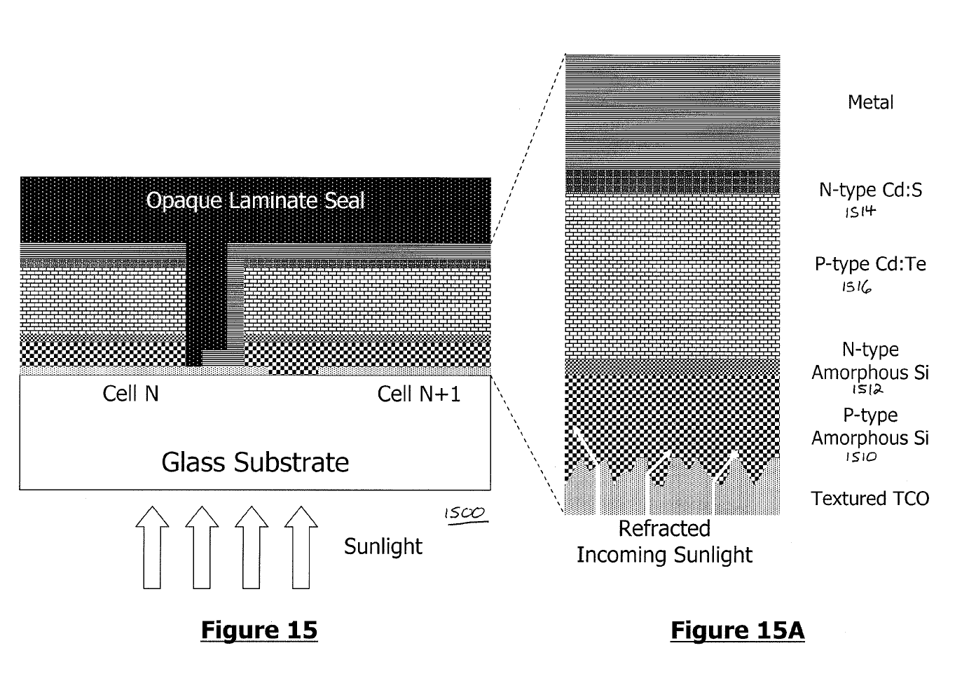

Nothing technically limits this approach to the use of amorphous thin film silicon with single crystal silicon. It can be used to fabricate polycrystalline silicon thin film with single crystal silicon or with other semiconductor materials such as Cd:Te, CIS, etc. FIGS. 15-15A show simplified cross-sectional and enlarged cross-sectional views, respectively, of an embodiment of a cell 1500 which includes a first P/N junction between P- and N-type amorphous silicon layers 1510 and 1512 respectively formed from liquid silane, and a second P/N junction between N-type Cd:S 1514 and P-type Cd:Te 1516.

Steps for Making Invention

### FIRST EMBODIMENT

Superstrate

(1) Clean the flexible substrate and etch to texture the surface. Gratings can also be patterned on the flexible substrate.
(2) Inkjet print an adhesion promoter film
(3) Inkjet print p-type amorphous silicon
(4) Inkjet print p-type amorphous silicon. For undoped amorphous silicon films, an additional process step requiring spin-on dopant films will be needed.
(5) The amorphous silicon film will be annealed using laser or RTA to crystallize the films and reduce defects. Both the inkjet printing of the absorber and the annealing can be done in a nitrogenous atmosphere.
(6) A transparent conductive oxide layer will then be inkjet printed followed by inkjet printing of an antireflective coating.
(7) Spin coat or inkjet print the encapsulant
(8) Laser scribing will be used to isolate the cells and to create the contacts.
(9) The contact metallization will then be inkjet printed to create the functional solar cells.

### SECOND EMBODIMENT

Superstrate

(1) Clean flexible or fixed substrate. In some embodiments, etch to texture surface or pattern grating structures on the surface.
(2) Deposit Transparent Conductive Oxide. If deposited by CVD or coated as a liquid paste, the film can be automatically textured during deposition. If the film is formed by sputtering, an acid or plasma treatment textures the film after deposition,
(3) Using a laser, burn (cut) isolation lines in the TCO layer in order to isolate the individual photovoltaic cells. Clean substrate.
(4) Optionally, coat an adhesion promoter film.
(5) Coat a p-type amorphous silicon.
(6) Coat an n-type amorphous silicon. For undoped amorphous silicon films, an additional process step requiring spin-on dopant films may be needed. Alternatively, rather than coating with an n type material, the film can be doped using a diffusion furnace or optical annealing system in a POCl₃ or other atmosphere.
(7) The amorphous silicon film is annealed using a laser to crystallize the films and reduce defects. Both the coating of the absorber and the annealing are performed in a nitrogen or argon atmosphere.
(8) Cut through the silicon absorber layers using a laser to open contact area to underlying TCO layer.
(9) Cut into top n type silicon layer to open a contact area.
(10) Inkjet or screen print a film comprising metallic material such as aluminum or silver paste, into a pattern making separate contacts to the p and n layers.
(11) The cell is fired in an oven to form ohmic contacts between the metal and semiconducting material.
(12) Test and inspect cells.
(13) If the substrate is flexible an encapsulant and protective layer are applied, followed by an anti-reflective AR coating made from nanoporous material (including polyelectrolyte multilayers). The AR film can be coated and heat treated. If the substrate is glass, the light facing surface is coated with the AR film.

### EMBODIMENT

Substrate

(1) Clean flexible or fixed substrate. In one embodiment, etch to texture surface or pattern grating structures on the surface.
(2) Coat or vacuum deposit aluminum or other metal layer. If coated, the substrate would be fired to remove liquid to form solid coating. Etch if needed to texture film. Optionally, deposit second thin metal layer to block aluminum from dissolving in silicon to form eutectic.
(3) Using a laser, burn (cut) isolation lines in the metal layers in order to isolate the individual photovoltaic cells. Clean substrate.
(4) Optionally, coat an adhesion promoter film.
(5) Coat p-type amorphous silicon.
(6) Coat n-type amorphous silicon. For undoped amorphous silicon films, an additional process step requiring spin-on dopant films will be needed. Alternatively, rather than coating with an n type material, the film can be doped using a diffusion furnace or optical annealing system in a POCl₃ or other atmosphere.
(7) Anneal the amorphous silicon film using laser re-crystallization. A conventional furnace may be available for this due to the presence of a metal layer, and its low melting point compared to temperatures required for silicon annealing. Both the coating of the absorber and the annealing can be done in a nitrogen or argon atmosphere.
(8) Deposit Transparent Conductive Oxide. If deposited by CVD or coated as a liquid paste, the film can be automatically textured during deposition. If it is formed by sputtering, an acid or plasma treatment textures the film.
(9) Cut through the silicon absorber layers using a laser to open contact area to underlying metal layer.
(10) Cut into top n type silicon layer to open contact area.
(11) Inkjet or screen print film containing metallic material such as aluminum or silver paste into a pattern, making separate contacts to the p and n layers.
(12) The cell is fired in an oven to form ohmic contacts between the metal and semiconducting material.
(13) Test and inspect cells.
(14) If the substrate is flexible, an encapsulant and a protective layer are applied, followed by an anti-reflective (AR) coating that may be made from nanoporous material (including polyelectrolyte multilayers). The AR film can be coated and heat treated. If the substrate is glass the light facing surface is coated with the AR film.

Although the above embodiments have been described using a selected sequence of steps, any combination of any elements of steps described as well as others may be used. Additionally, certain steps may be combined and/or eliminated depending upon the embodiment. Of course there can be other variations, modifications, and alternatives.

In summary, through the use of inkjet, or other forms of liquid coating technologies, the complex equipment needed for vacuum deposition and its limited material throughput is eliminated, thereby substantially reducing the cost of manufacture. Films deposited using liquid silanes on flexible or fixed substrates, are polymerized by UV radiation and then converted to amorphous silicon after subsequent heat treatment. After annealing under inert atmosphere using a laser, or other techniques such as optical furnace, flash lamp, rapid thermal or conventional furnace, the amorphous silicon film is converted to polycrystalline, or microcrystalline depending on the application. This low cost method for fabricating high quality silicon films when combined with proper surface texturing and/or diffraction techniques can yield solar conversion efficiencies consistent with state of the art solar photovoltaics. Moreover, films formed in this fashion can be combined as multi-junction cells or with other crystalline or thin film cells to further enhance conversion efficiencies. Due to the low manufacturing costs, applications such as bifacial having active solar cells collecting light from both sides of a planar structure become practical.

While the above is a full description of certain specific embodiments, various modifications, alternative constructions and equivalents may be used. For example, coating by inkjet printing or other techniques is not limited to liquid silane material. Certain embodiments may employ inkjet printing of a metallic material such as aluminum or silver paste to form patterns of conductive lines interconnecting the solar cells, followed by a brief high temperature firing of the deposited material in a furnace to drive off the solvent and cause ohmic contacts with the underlying silicon or metal layers. In an alternative embodiment, screen printing may be used to print the metal patterns for interconnection. According to an embodiment, wired busbars may be applied to string the high current cells together and bring the leads out for interconnection. In an embodiment, cells are built on a glass substrate using a superstrate cell design, in which case high current capable busbars are bonded to the metal using either laser or ultrasonic bonding treatment.

According to certain embodiments, a transparent encapsulant and protective laminate film(s) may be applied to the front of the flexible solar cells comprising multiple cells, in order to protect the solar cells from the environment. In an embodiment, a transparent durable rigid material such as sheet glass is laminated and sealed to the flexible substrate. In an embodiment, the cell design is a superstrate and the underlying substrate is transparent and the encapsulant and laminate films do not need to be transparent. In an embodiment, the cell design is a superstrate and the underlying substrate is rigid and transparent, such as sheet glass. In an embodiment, an anti-reflective AR coating made from nanoporous material (including polyelectrolyte multilayers) is coated over the exterior transparent surface and annealed under heat. In an embodiment, an anti-reflective AR coating is deposited in an LPCVD or physical sputter deposition chamber over the exterior transparent surface and annealed under heat.

Certain embodiments may apply an amorphous silicon film using liquid silane coating followed by polymerization and heat treatment, to a Cd:Te thin film photovoltaic cell in order to increase the Cd:Te cell efficiency. In an alternative embodiment, a polycrystalline or microcrystalline silicon film is applied to a Cd:Te cell by coating the cell with liquid silane followed by polymerization, heat and annealing. In an alternative embodiment, the silicon film may be applied and annealed before the Cd:Te cell layers are applied. In alternative embodiments, other solar cells designs may be used, such as single crystal silicon, Copper Indium Selenium CIS, Copper Indium Gallium Selenide CIGS, Gallium Arsenide GaAs and others. In still other embodiments, a fixed substrate may be used in place of the flexible substrate.

Certain embodiments may integrate silicon photovoltaic thin films using the liquid silane, followed by UV polymerization, heat treatment and annealing to cost effectively form active solar cells applied to both sides of a planar substrate for the purpose of collecting light impinging on both sides of a bifacial solar cell. In an embodiment, such a bifacial cell comprises the silicon film formed from the liquid silane being positioned on a side of the photovoltaic cell opposite of materials using a different technique, for example single crystal silicon, amorphous silicon vacuum deposited, Cd:Te, CIS, CIGS, GaAs, etc.

The above description focuses upon the application of a liquid silane in monomer form, followed by polymerization. However, this is not required by the present invention.

According to alternative embodiments, a liquid silane in polymer form may be coated on selected areas. Such a liquid silane already in polymer form, may comprise a polymerized silane in a liquid carrier. In certain embodiments this liquid carrier could be a solvent, and in certain embodiments this liquid carrier could be the silane in monomer form. Following coating of the liquid silane by inkjet printing or another of the techniques referenced above, the polymerized silane could be converted to solid form by removal of the liquid carrier.

The above description focuses upon the application of a liquid silane to form a single junction in a PV cell. However, this is not required by the present invention.

According to alternative embodiments, applications of liquid silane may be repeated to form PV cells having multiple P/N junctions. For example, in one embodiment a liquid silane may first be applied in the process of forming a P/N junction out of silicon having a greater degree of crystalline order—for example polycrystalline and/or microcrystalline. Later, liquid silane could again be applied to form a second P/N junction from silicon having a lesser degree of crystalline order, for example amorphous silicon and/or microcrystalline silicon. This order of processing would avoid exposing a-Si formed initially, to later annealing that would likely convert it to a higher degree of crystalline order.

While the above is a full description of certain specific embodiments, various modifications, alternative constructions and equivalents may be used. Therefore, the above description and illustrations should not be taken as limiting the scope of the present invention which is defined by the appended claims.

What is claimed is:

1. A process comprising:
providing a substrate;
coating a selected region with a liquid silane;
converting the liquid silane to a polymerized material; and
incorporating the polymerized material as an absorber layer in a photovoltaic cell.

2. The process of claim 1 wherein the liquid silane comprises a cyclic silane.

3. The process of claim 2 wherein the cyclic silane is selected from cyclopentasilane (C₅H₁₀), cyclohexasilane (C₆H₁₂), a cyclosilane having a ligand containing Boron or other Group III element), or a cyclosilane having a ligand containing phosphorous or another group V element.

4. The process of claim 2 wherein the cyclic silane comprises a cyclosilane having a ligand attached to a silicon atom in the ring to alter a liquid silane property selected from viscosity, melting point, boiling point, and a susceptibility to polymerization upon exposure to radiation.

5. The process of claim 1 wherein providing the substrate comprises providing a rigid substrate comprising metal, glass, quartz, ceramic, plastic, or a composite.

6. The process of claim 1 wherein providing the substrate comprises providing a flexible substrate comprising metal, plastic, mylar, or a composite sheet.

7. The process of claim 1 wherein selected regions of the substrate are coated with the liquid silane utilizing a technique selected from inkjet printing, screen printing, roller coating, gravure coating, curtain coating, or spray coating.

8. The process of claim 1 wherein converting the liquid silane to a polymerized material comprises:
exposing the liquid silane to radiation of UV or a shorter wavelength; and
applying heat treatment.

9. The process of claim 8 wherein the heat treatment comprises exposure to infra-red radiation, hot plates, or furnaces in a controlled ramp and dwell time.

10. The process of claim 8 wherein the heat treatment and the radiation exposure are performed in concert.

11. The process of claim 8 further comprising annealing the polymerized material to form polycrystalline silicon.

12. The process of claim 11 wherein the annealing comprises exposure to a laser, exposure to a flash lamp, exposure to an optical furnace, rapid thermal annealing (RTA), furnace heating, or a combination of these annealing techniques.

13. The process of claim 8 wherein converting the liquid silane to a polymerized material comprises:
converting the polymerized material to silicon having a grain size of between about 0.5-20 μm.

14. The process of claim 1 wherein:
the selected region of the substrate is coated with the liquid silane containing Boron or another Group III element, and the liquid silane is converted into a p-type absorber layer, the process further comprising,
coating the p-type absorber layer with a second liquid silane containing Phosphorous or another Group V element, and
converting the second liquid silane to an n-type absorber layer prior to incorporation into the photovoltaic cell.

15. The process of claim 1 wherein:
the selected region of the substrate is coated with the liquid silane containing Phosphorus or another Group V element, and the liquid silane is converted into an n-type absorber layer, the process further comprising,
coating the n-type absorber layer with a second liquid silane containing Boron or another Group III element, and
converting the second liquid silane to a p-type absorber layer prior to incorporation into the photovoltaic cell.

16. The process of claim 1 wherein:
the substrate is provided with a P/N junction of a first type already present therein; and
the absorber layer comprises part of a second P/N junction of a second type different from the first type.

17. The process of claim 16 wherein the first type is in a material selected from amorphous silicon, multicrystalline silicon, polycrystalline silicon, single crystal silicon, GaAs, Cd:Te, CIS, or CIGS.

18. The process of claim 16 wherein the second type is in another material different from the material and selected from amorphous silicon, multicrystalline silicon, polycrystalline silicon, single crystal silicon, GaAs, Cd:Te, CIS, or CIGS.

19. The process of claim 1 further comprising texturizing the substrate prior to coating with the liquid silane.

20. The process of claim 19 wherein the substrate is texturized by exposure to acid, a plasma, or a laser.

21. The process of claim 1 further comprising forming a Transparent Conductive Oxide (TCO) layer over the absorber layer.

22. The process of claim 21 further comprising texturizing the TCO layer by exposure to acid, a plasma, or a laser, or by controlling conditions during deposition of the TCO layer.

23. The process of claim 21 further comprising removing portions of the TCO layer by laser ablation after incorporation into the photovoltaic cell.

24. The process of claim 1 further comprising forming a Transparent Conductive Oxide (TCO) layer over the substrate prior to coating with the liquid silane, wherein the substrate is transparent to incident light.

25. The process of claim 1 further comprising forming incorporating a diffraction grating in the photovoltaic cell.

26. The process of claim 25 wherein the diffraction grating is printed on the substrate separated by intervening layers from the direction of incident light.

27. The process of claim 25 wherein the diffraction grating is printed on a top layer of the solar cell configured to face incident light.

28. The process of claim 25 wherein the diffraction grating is etched as a pattern in the substrate.

29. The process of claim 25 wherein the diffraction grating is formed from silicon oxide, Si₃N₄, polyimide, or silicon.

30. The process of claim 1 wherein:
the substrate is provided with a P/N junction on a first side; and
the absorber layer is formed on a second side of the substrate opposite to the first side, such that the photovoltaic cell is of a bifacial type.

31. The process of claim 11 wherein following the annealing, the process further comprises:
coating a second selected region with additional liquid silane;
converting the additional liquid silane to a second polymerized material, and
incorporating the second polymerized material in the photovoltaic cell.

32. The process of claim 31 wherein the second polymerized material comprises amorphous silicon, microcrystalline silicon, or a combination of amorphous silicon and microcrystalline silicon.

33. A process for fabricating a photovoltaic cell, the process comprising:
forming a silicon absorber layer by applying liquid silane to a surface and then applying a heat treatment to the liquid silane; and
forming an additional layer over the silicon absorber layer.

34. The process of claim 33 wherein the liquid silane comprises a silane monomer, the process further comprising polymerizing the silane monomer by exposure to radiation.

35. The process of claim 33 wherein the liquid silane comprises a silane polymer in a liquid carrier.

36. The process of claim 33 wherein the silicon absorber layer comprises polysilicon formed by annealing the polymerized liquid silane, the polysilicon having a thickness of between about 0.5-20 μm.

37. The process of claim 33 wherein the surface comprises a substrate configured to face away from incident light, such that a substrate-type photovoltaic cell is fabricated.

38. The process of claim 33 wherein the surface comprises a transparent substrate configured to face incident light, such that a superstrate-type photovoltaic cell is fabricated.

39. The process of claim 33 wherein the surface comprises a surface of a substrate having an existing P/N junction.

40. The process of claim 39 wherein the surface is opposite a second side of the substrate having the existing P/N junction, such that a bifacial-type photovoltaic cell is fabricated.

41. The process of claim 39 wherein the surface is on a same side of the substrate having the existing P/N junction, such that a multijunction-type photovoltaic cell is fabricated.

42. A photovoltaic cell comprising:
a substrate; and
a polycrystalline silicon absorber layer formed over the substrate and having a thickness of between about 0.5-20 μm and comprising a P/N junction.

43. The photovoltaic cell of claim 42 of a superstrate type, wherein the substrate is transparent to incident light.

44. The photovoltaic cell of claim 42 of a substrate type, wherein the substrate is opaque.

45. The photovoltaic cell of claim 42 wherein the substrate comprises an existing P/N junction.

46. The photovoltaic cell of claim 45 of a bifacial type, wherein the silicon absorber layer is formed over a first side of the substrate opposite to a second side comprising the existing P/N junction.

47. The photovoltaic cell of claim 45 of a multi-junction type, wherein the silicon absorber layer is formed on a same side of the substrate as the existing P/N junction.

48. The photovoltaic cell of claim 45 wherein the silicon absorber layer comprises a second P/N junction of a same type as the existing P/N junction.

49. The photovoltaic cell of claim 48 wherein the type of the second P/N junction is selected from amorphous silicon, multicrystalline silicon, polycrystalline silicon, single crystal silicon, GaAs, Cd:Te, CIS, or CIGS.

50. The photovoltaic cell of claim 45 wherein the silicon absorber layer comprises a second P/N junction of a different type as the existing P/N junction.

51. The photovoltaic cell of claim 50 wherein the type of the second P/N junction is selected from amorphous silicon, multicrystalline silicon, polycrystalline silicon, single crystal silicon, GaAs, Cd:Te, CIS, or CIGS.

52. The photovoltaic cell of claim 41 further comprising a diffraction grating.

53. The photovoltaic cell of claim 41 further comprising a transparent conducting oxide (TCO) layer.
